(19) United States
(12) Patent Application Publication
(10) Pub. No.: US 2008/0178929 A1
(43) Pub. Date: Jul. 31, 2008

(54) SYSTEM AND METHOD OF IMPROVING THE DIELECTRIC PROPERTIES OF LAMINATES

(76) Inventors: Richard Skov, Spencer, MA (US); Eric Barker, Longmeadow, MA (US); Kenneth Burnham, Warren, MA (US); Winsor Cho, Sturbridge, MA (US); John Pennace, Paxton, MA (US)

Correspondence Address: GAUTHIER & CONNORS, LLP, 225 FRANKLIN STREET, SUITE 2300, BOSTON, MA, 02110, US

(21) Appl. No.: 12/016,553

(22) Filed: Jan. 18, 2008

Related U.S. Application Data
(60) Provisional application No. 60/886,680, filed on Jan. 26, 2007.

(51) Int. Cl. H01L 31/042; H02N 6/00

(52) U.S. Cl. 136/251; 136/252; 524/563

(57) ABSTRACT

A laminate of dielectric materials is disclosed for use in protecting an electronic device. The laminate includes at least one layer of a polymeric material having an active material dispersed within the polymeric material and having a first thickness. The active material is responsive to external electric fields such that a higher voltage external electric field may be applied to one side of the laminate without any voltage passing through the laminate than a maximum voltage that could be applied to the laminate without passing through the laminate when the active material is not present within the polymeric material having the first thickness.

### PRIORITY

This application claims priority to U.S. Provisional Patent Application Ser. No. 60/886,680 filed Jan. 26, 2007.

### BACKGROUND

The invention generally relates to dielectric films and laminates for use with electrical devices and relates in particular to dielectric layers, top layers and backing layers in electrical devices, as well as adhesive layers for forming such laminates.

The protection of electrical devices from harsh environments is a necessity for the proper operation and the expected useful life of such devices. Many electrical devices are enclosed within a housing, but some, such as for example, illuminated signs (e.g., electroluminescent, electrophoretic, cholosteric, liquid crystal and other field effect displays), data input devices (e.g., keyboards, key panels and membrane switches) and photovoltaic panels (e.g., solar panels) are exposed to the environment. Environmental factors such as water, oxygen, humidity, vapor, dust, dirt, sunlight, temperature extremes and various chemical agents are just some of the harsh conditions to which electrical devices are exposed.

To protect these devices from environmental exposure, it is typically necessary to affix a protective barrier to at least part of the electrical device. One form of such protective barrier is a flexible laminate of dielectric polymeric materials. Here, a composite is constructed to meet multiple environmental conditions including incorporating protective layers to protect the other layers of the composite itself. Electrical interference may also present problems in certain environments with fields generated by atmospheric triboelectric effects, by the device itself or by other equipment that is near the device. These fields could compromise part of or the entire protective barrier, and may cause such protective layers to undergo degradation of some or all of the components of the protective barrier over time. This can occur abruptly due to such fields causing discharge within the protective barrier.

Certain types of electrical devices include a common ground within the device, and in some cases, the ground may be coupled to an exterior surface to permit discharge of any exterior high voltage to ground. In other types of electrical devices however, the device may be provided as a dielectric and not include a common ground that may be coupled to the exterior of the device. For example, photovoltaic cells and photovoltaic arrays are generally protected by a dielectric composite, possibly with a back panel for protecting wiring that runs under the photovoltaic cells. Such dielectric composites cannot be easily protected against high external voltages by coupling the exterior to ground.

There is a need, therefore, for a protective laminate for electrical devices that provides improved dielectric properties, and further that provides improved protection against a maximum voltage that may be tolerated by the device without causing electrical discharge within the device.

### SUMMARY

The invention provides a laminate of dielectric materials for use in protecting an electronic device. The laminate includes at least one layer of a polymeric material having an active material dispersed within the polymeric material and having a first thickness. In accordance with an embodiment, the active material is responsive to external electric fields such that a higher voltage external electric field may be applied to one side of the laminate without any voltage passing through the laminate than a maximum voltage that could be applied to the laminate without passing through the laminate than when the active material is not present within the polymeric material having the first thickness. In certain embodiments, this may be achieved by the active material absorbing electric fields. In further embodiments, the active material may include an organo-salt, the polymeric material may be an adhesive, and the active material may absorb the electric fields by becoming polarized in the presence of the electric fields, thereby effectively changing the dielectric properties of the laminate.

In accordance with further embodiments, the invention provides a protective laminate for protecting electrical and electronic devices that includes a composite of between 0.5-45% by weight of an organo-salt in at least one polymeric layer of the protective laminate. The composite of the organo-salt and the polymeric layer provide a homogeneous combination that is in a single phase, and the organo-salts mitigate the effect of an electric field on the laminate and thereby lessen the driving force to discharge through one or more of the layers. The active material in the laminate may respond to the presence of the electric field by becoming polarized in a uniform direction, and the active material may include an organo-salt. The layer of polymeric material may include between about 0.5%-45% of the active material and the laminate may be applied to a photovoltaic device. The active material may be included within at least two layers of polymeric materials, and at least one of the polymeric materials may be an adhesive such as a pressure sensitive adhesive. The combination of the active material within the polymeric structure would result in the mixture exhibiting a different, most often higher, dielectric constant than the base polymeric moiety without said active material.

In accordance with a further embodiment, the invention provides a protective laminate for protecting electrical and electronic devices that includes between 0.5-45% by weight of an organo-salt in at least one polymeric layer of the protective laminate. The combination of the organo-salt and the polymeric layer provides a homogeneous combination that is in a single phase. The organo-salts mitigate the effect of an electric field on the laminate and thereby lessen the driving force to discharge in one or more of the layers. The preferred concentration of the organo-salt based on dry weight % may be between 1-10%. The field of use may be as a protective back panel in a photovoltaic-application, or the organo-salt doped adhesive may be used in an electrophoretic device, displays and other devices. The organo-salt may be in an adhesive layer used as a protective cover for a membrane switch, or the organo-salt may be in an adhesive layer used as a bonding adhesive between layers within a membrane switch. The use of the organo-salt doped adhesive may be in a liquid crystal or plasma display.

In accordance with a further embodiment, the invention provides a laminate of dielectric materials for use in protecting an electronic device. The laminate includes at least one layer of a polymeric material having an organo-salt dispersed within the polymeric material for becoming polarized in the presence of an electric field and thereby absorbing portions of the electric field that pass through the polymeric material to thereby effectively change the dielectric strength of the laminate in the presence of the electric field. The polymeric material may be an adhesive, and may include between about 0.5%-45% by dry weight of the organo-salt, and may preferably include between about 1% to about 20% by dry weight. The laminate may be applied to a back side of a photovoltaic panel and may include a polymeric material such as ethylene vinyl acetate for encapsulating the photovoltaic panel. In certain embodiments, the ethylene vinyl acetate may include between about 0.5% and about 35% by dry weight of the organo-salt, and may preferably include between about 1% to about 10% by dry weight of the organo-salt.

In accordance with a further embodiment, the invention provides a method of protecting an electronic device against an electric field. The method includes the steps of applying a laminate to the electronic device, the laminate including at least one layer of a polymeric material having an active material dispersed within the polymeric material, and permitting the laminate to be exposed to the electric field. The method further provides the steps of increasing a dielectric strength of the layer of polymeric material having the active material dispersed within the polymeric material from a first dielectric constant that exists in the absence of the electric field, to a second dielectric constant that exists in the presence of the electric field, and preventing an electrical discharge from the electric field to be coupled to the electronic device due to the increase of the dielectric strength increased to the second dielectric constant.

### BRIEF DESCRIPTION OF THE ILLUSTRATED EMBODIMENT

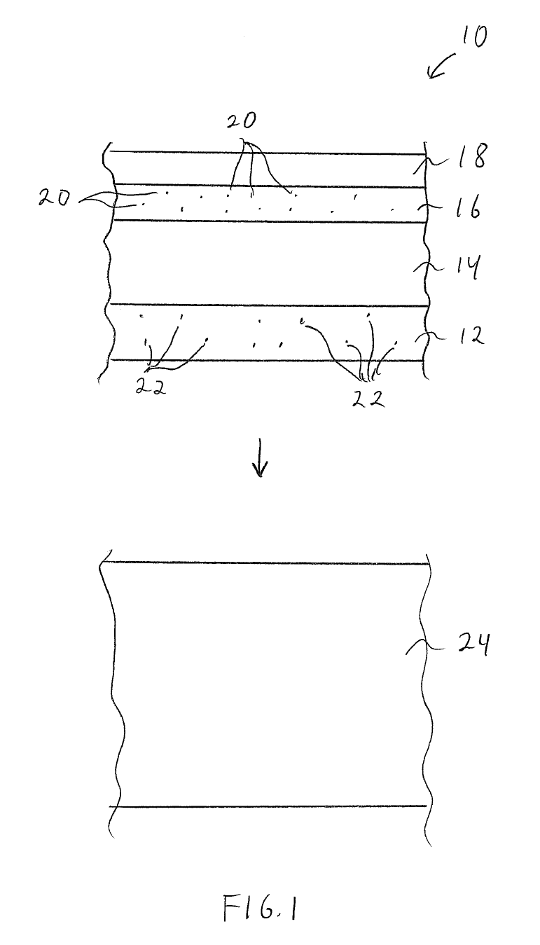

The following description may be further understood with reference to the accompanying drawing in which FIG. 1 shows a protective laminate in accordance with an embodiment of the invention being applied to an electrical device. The drawing is shown for illustrative purposes only.

### DETAILED DESCRIPTION

The source of discharges that occur in protective barriers for electrical devices generally relate to changes in the electrical behavior of one or more layers that include a contaminant or void (e.g., bubble). Such contaminants or voids are susceptible to accumulating liquids or vapors within some interstitial space of one (or more) of the components, and thereby provide weaknesses in the dielectric properties of the material. Electrically induced oxidation or chemically induced degradation may produce a micro network capable of conducting a small electrical current even when the potential difference may be lower than the dielectric breakdown strength of the material.

Protective barriers that do not include a conductive layer generally do not have a ready means for discharging electrical potential that builds up within the device. One such example can be found in photovoltaic cells and photovoltaic arrays. Here, a major protective laminated composite is on the back panel, i.e., away from the light sensitive portion of the array. The primary purpose of these back panel protective laminates is to protect the wiring that runs under the photovoltaic cells from the effects of water, moisture, dust, dirt and all the other environmental factors that would tend to degrade the efficiency of the array. Charges that build up in the protective laminate are not discharged through a conductive layer, but rather build up across the dielectric materials of the protective laminate.

Applicants have discovered that the addition of certain field mitigating material in one or more of the layers of the protective laminate may increase the field required to initiate a change in electrical behavior of the dielectric material. Or expressed in different terms, increase the threshold applied voltage before the change will occur.

FIG. 1 for example, shows a photovoltaic array back panel 10 that includes a layer 12 of ethylene vinyl acetate (EVA) of about 100 microns that is used to encapsulate the photovoltaic panel. In various embodiments, multiple layers of EVA may be employed. The initial layer is deposited with the application of heat to cause the EVA to flow onto the back panel surface establishing an intimate surface contact with the device.

On the EVA layer is a layer 14 of polyethylene terephthalate (PET) of about 100 microns of EVA that is used as a primer for the encapsulant (often another, thicker, form of EVA) in the photovoltaic panel. PET also affords some protection against impact, tear and other mechanical assaults. The PET, however, does not have a 20+ year outdoor durability, even in indirect sunlight exposures.

A layer 18 of polyvinyl fluoride (PVF) of about 25 microns is laminated to the PET layer via an adhesive 16. The PVF layer protects the PET layer and for that matter, the entire composite from the effects of photo degradation. Besides protecting the composite from the adverse effects of sunlight, PVF also affords a low surface energy and a self-cleaning property preventing particulate matter from adhering to the surface.

The adhesive layer 16 between the PVF layer and PET layer is an adhesive such as, for example, a pressure sensitive adhesive, FLEXcon adhesive # V-250. This pressure-sensitive adhesive of about 25 microns, in addition to bonding the polyvinyl fluoride layer to the rest of the laminated composite, also allows independent movement between the PET and the PVF layers that may compensate for differential thermal expansion and contraction properties between those two polymer films, thus preventing curl or puckering problems that can occur with more rigidly bonded laminates. One additional feature of the pressure sensitive adhesive layer is that it is where one can incorporate those materials which would mitigate the effects of the change in electrical behavior due to an electric field.

Referring again to the non-limiting example of photovoltaic devices, there exist various test protocols for measuring the minimum electric field that may be applied to the device without causing discharge through the photovoltaic device. For example, in Europe a test procedure is designated IEC 61730-2 and is entitled Photovoltaic (PV) Module Safety Qualification test. For example, a test procedure may involve placing a sample of the laminated composite between electrodes such that the field can be applied and the potential across said electrodes can be varied, increasing until such time as a partial discharge, i.e., the breakdown of one of the layers of the composites occurs. The raw data is then statistically converted to a final partial discharge rating. The minimum rating may be, for example, 1000 volts, and it may be required that all back panels be able to deal with this minimum.

One of the ways to achieve the minimum 1000 volt rating is to increase the thickness of the total laminated composite. The greater the thickness, the further the distance between the two electrodes, the lower the field strength is at any specific location within the laminate structure. Thus, the higher the total applied voltage in order to achieve a partial discharge. While this is a workable solution to this qualification test, it does add cost, unnecessary thickness, unnecessary stiffness and unnecessary weight to the total photovoltaic array.

Applicants have found that certain polar materials may be added to one or more of the layers of the protective composite in accordance with various embodiments of the invention. As shown in FIG. 1, for example, the adhesive layer 16 includes active material 20 such as organo-salts (e.g., quaternary ammonium salts) in an embodiment, and the EVA layer 12 may also include such active materials 22 in further embodiments. The protective laminate 10 is applied to an electrical device 24 using the EVA layer 12.

The use of such active material, such as organo-salts, incorporated within polymeric materials may alter the electrical effects of a polymer. It is believed that the effects of such additives (such as organo-salts) to various polymeric layers are to change, e.g., increase, the dielectric properties of the mixture as compared to the dielectric properties of the polymeric layers when no such additives are included. Specifically, these organo-salts raise the field needed to initiate a partial dielectric breakdown. In other embodiment of this invention, the organo-salts may be used to change, e.g., raise, the dielectric constant of a polymeric layer so as to permit the application of a greater electric field. Such composites may also be suitable for applications involving display such as electrophoretic, cholosteric, liquid crystal and other such field effect displays. Other electrical devices could also benefit from the use of this invention.

The organo-salts may be any of (but not limited to): quaternary ammonium salts, organo-sulfates, fluoroborates and other salt-like materials having some organic functionality including conductive polymers. The organic functionality facilitates the salt's organic compatibility with the polymeric material. It is important that the addition of these organo-salts be such that the mixture with the polymer component is uniform and as near to homogeneous as possible in certain embodiments. Phase separation of the salt from the adhesive will result in less of a favorable electrical effect and potentially loss of adhesive bond to the substrates. A method to help determine homogeneity is as follows.

First, a polar material is combined with the polymeric material in about five different concentrations (typically between about 0.5% to about 45% by weight). Then the adhesive-salt composite is applied to a (about 1.5 mil) substrate and permitted to dry and cure. The surface of the composite is then inspected after a short period of time. If the salt has crystallized out or bloomed to the surface, then the combination of components is not compatible. If, on the other hand, the composite is clear, it is subject to the next level of compatibility testing. The samples should then be subjected to an exposure test in which the samples are exposed to 100° F. with 95% relative humidity for 3 days. The samples are then again inspected to determine whether the polar material has migrated toward either surface. If there has been no migration of the polar material and the composite remains clear, then that combination is a stable homogeneous mixture.

### Example 1

An adhesive doped with a compatible organo-salt was prepared as follows: to 120 pounds (dry weight) of V-340 Pressure Sensitive Adhesive (PSA) as sold by FLEXcon Company, Inc. of Spencer, Mass., 7 pounds (dry weight) of Arquad HTL8-MS quaternary ammonium compound, as sold by Armour and Company Corporation of Chicago, Ill., (about 6%), which is an organo-salt. This blend was then coated to a thickness of about 1 mil on a 5 mil PET. After drying said adhesive blend, a 1 mil PVF film was laminated to the adhesive coated side of the PET.

In a separate step, 4 mil of EVA was laminated to the PET side opposite the PVF layer (note FIG. 1). A second sample was similarly prepared, but with no organo-salt dopant added to FLEXcon's V-340 adhesive. Samples from both doped and non-doped V-340 were sent to TÜV Rheinland Immissionsschutz und Energiesysteme GmbH for testing as per the IEC 61730-2 Photovoltaic (PV) module safety qualification test. The threshold rating from this test to pass is 1000 volts. The sample set prepared with doped adhesive came in at 1040 volts and the sample set prepared with undoped adhesive yield only 995 volts. The exact doping levels and the exact organo-salt to use is a function of the adhesive chosen to be doped and the adhesive choice is primarily driven by the application requirements.

Stable, non-phase separating blends of organo-salts within various adhesives have been made in concentration of dopant from 0.5% to 45% dry weight to dry weight. For applications which are directed towards the migration of electrical discharge, most applications requirements can be met with blends between 1-10% on dry weight. The amount that should be used is that which meets the required electrical property, with the least, most economical, amount of dopant.

The mitigation of electrical discharge from a protective laminate is not relegated to a single application such as photovoltaics, but in any other application, electronic displays for example, there is a need to protect some electrical or electronic device or part of a device, from environmental attacks, and there is concern that one or more layers of the composite laminate may be subjected to conditions that may result in such discharge. Further, it may be necessary to add such organo-salts to more than one layer of the protective laminate.

In the example shown in FIG. 1, if the required performance threshold was higher it may be needed to add a similar dopant to the EVA layer. In particular, the above organo-salt may be added to the EVA layer in an amount of between about 1% and about 10% by dry weight preferred, but in other cases 0.5% to 35% is a workable range. The same conditions for a homogeneous, non-phase separating blend would apply. Other organo-salts may function as well in the EVA layer.

In another area of use, membrane switches often use coated one side and/or coated two side tapes for use as spacers or protective over-laminates. Often these tapes consist of a polymeric film coated one or both sides with a PSA. With at least one PSA layer available, the organo-salts may be added in an amount of between about 1% and about 10% by dry weight is the preferred range. Of course the second adhesive layer may also be doped with active materials if needed.

Similarly, if it were necessary to bond something else to a photovoltaic array, an additional structural backing plate or glass for example, a second bonding layer (PSA, or heat activated adhesive) would be needed. The additional layers may also be candidates for doping with organo-salts. This could be even more important in those cases where a 3 mil, 5 mil, or thicker supporting film, is not required because the second adhesive side is being bonded to another structural element—glass, thicker formed thermoset or thermoplastic structural piece, etc.—thus a thinner, less robust laminate can be used. This thinner laminate however, still needs to pass the IEC 61730-2 requirement.

A more demanding application involving a thinner laminate may require more organo-salt in more of the layers in order for the laminate to meet the required electrical requirements. Many further such protective and fastening (bonding) laminates used in a variety of electric or electronic applications may also benefit from this invention.

In yet a further embodiment, phase compatible organo-salts may be used within polymeric systems in electrophoretic displays. These displays have particles suspended in a liquid, having electric field susceptibility, with the particles being of different colors (usually black and white) or spherical particles with each hemisphere of different color where each color moiety can be oriented by the changing direction of the applied field. These liquid suspended particles are encapsulated in a polymeric or sometimes a glass encapsulant. These capsules are often dispersed in another polymer matrix (often referred to as an electrophoretic ink) which then may be applied to glass or polymeric films, substrate coated with transparent electrode, e.g., Indium tin Oxide (ITO).

There is also a back plane that has an array of electrodes, which can complete the field for a specific location, thus allowing for a display having controlled indicia. It has been found that incorporating organo-salts as described effectively promotes the desired electrophoretic display function.

### Example 2

A test was conducted on an electrophoretic ink coated on an ITO coated clear PET film. This was bonded to a conductive layer consisting of a vacuum metallized PET film coated with a silicone release coating, with FLEXcon's V-340 pressure sensitive adhesive.

Electrodes were attached to both the metallized film and the ITO coated film. A 15 volt potential was applied, which resulted in no change, i.e., no orientation of the particles in the electrophoretic ink. In a similar fashion, a second sample was prepared and this time the V-340 was doped with 10% on dry weight, Arquad HTL8-MS quaternary ammonium compound, as sold by Armour and Company Corporation of Chicago, Ill. This sample was also subjected to a 15 volt potential. This time there was an immediate response as the particles in the electrophoretic ink switched to dark state, and when the field was reversed the ink switched back to its original bright state. The switching threshold voltage was significantly reduced. It is anticipated that the ink itself, not just the attaching adhesive layer, will benefit from incorporating organo-salts as described here.

Those skilled in the art will appreciate that numerous modifications and variations may be made to the above disclosed embodiments without departing from the spirit and scope of the invention.

What is claimed is:

1. A laminate of dielectric materials for use in protecting an electronic device, said laminate including at least one layer of a polymeric material having an active material dispersed within the polymeric material having a first thickness, said active material being responsive to external electric fields such that a higher voltage external electric field may be applied to one side of the laminate without any voltage passing through the laminate than a maximum voltage that could be applied to the laminate without passing through the laminate when the active material is not present within the polymeric material having the first thickness.

2. The laminate as claimed in claim 1, wherein said active material reduces the electric field strength.

3. The laminate as claimed in claim 1, wherein the active material includes an organo-salt.

4. The laminate as claimed in claim 1, wherein the polymeric material is an adhesive.

5. The laminate as claimed in claim 1, wherein the active material reduces the electric field strength by becoming polarized in the presence of the electric fields.

6. The laminate as claimed in claim 1, wherein the active material changes its dielectric properties in the presence of the electric fields.

7. The laminate as claimed in claim 1, wherein the active material within the polymeric material respond to the presence of the electric field by becoming polarized in a uniform direction, and wherein the active material may include an organo-salt.

8. The laminate as claimed in claim 1, wherein the layer of polymeric material may include between about 0.5%-45% of the active material and wherein the laminate is adhered to a photovoltaic device.

9. The laminate as claimed in claim 1, wherein the active material is included within at least two layers of polymeric materials, and at least one layer of the polymeric materials is a pressure sensitive adhesive.

10. The laminate as claimed wherein the polymeric material together with the active material within the polymeric material provides a doped polymeric material that has a first dielectric constant that is different than a second dielectric constant that the doped polymeric material has when the external electric field is applied to the laminate.

11. A protective laminate for protecting electrical and electronic devices that includes a composite of between about 0.5-45% by weight of an organo-salt in at least one polymeric layer of the protective laminate, wherein the composite of the organo-salt and the polymeric layer provides a homogeneous combination that is in a single phase, and wherein the organo-salts mitigate the effect of an electric field on the laminate and thereby lessen a proclivity to discharge through one or more of the layers.

12. The protective laminate as claimed in claim 11, wherein a concentration of the organo-salt in the polymeric layer based on dry weight % may be between about 1-10%.

13. The protective laminate as claimed in claim 11, wherein the protective laminate is adhered to an electrical device.

14. The protective laminate as claimed in claim 13, wherein the electrical device is a photovoltaic device.

15. The protective laminate as claimed in claim 13, wherein the electrical device is a display device.

16. The protective laminate as claimed in claim 15, wherein the display device is a liquid crystal display device.

17. The protective laminate as claimed in claim 13, wherein the electrical device is a membrane switch.

18. A method of protecting an electronic device against an electric field, said method comprising the steps of:
applying a laminate to the electronic device, said laminate including at least one layer of a polymeric material having an active material dispersed within the polymeric material;
permitting the laminate to be exposed to the electric field;
increasing a dielectric strength of the layer of polymeric material having the active material dispersed within the polymeric material from a first dielectric constant that exists in the absence of the electric field, to a second dielectric constant that exists in the presence of the electric field; and
preventing an electrical discharge from the electric field to be coupled to the electronic device due to the increase of the dielectric strength increased to the second dielectric constant.

19. The method as claimed in claim 18, wherein the step of increasing the dielectric strength of the layer of polymeric material having the active material dispersed within the polymeric material to the second dielectric constant includes permitting the active material within the polymeric material becomes polarized in the presence of the electric field.

20. The method as claimed in claim 18, wherein the step of applying a laminate to the electronic device includes adhering an adhesive layer on the laminate to the electronic device.

21. The method as claimed in claim 20, wherein the adhesive layer is the polymeric material and the active material is dispersed within the adhesive layer.

22. The method as claimed in claim 18, wherein the at least one layer of polymeric material having the active material dispersed within the polymeric material includes between about 0.5%-45% by dry weight of the active material and the active material is an organo-salt.

23. The method as claimed in claim 22, wherein the polymeric material includes between about 1% to about 20% by dry weight of the organo-salt.

24. The method as claimed in claim 18, wherein the electronic device is a photovoltaic panel that includes ethylene vinyl acetate for encapsulating the photovoltaic panel.

25. The method as claimed in claim 24, wherein the ethylene vinyl acetate include between about 0.5% and about 35% by dry weight of the organo-salt.

26. The method as claimed in claim 24, wherein the ethylene vinyl acetate include between about 10% by dry weight of the organo-salt.
